(19) United States
(12) Patent Application Publication
(10) Pub. No.: US 2011/0037162 A1
(43) Pub. Date: Feb. 17, 2011

(54) HERMETIC PACKAGING AND METHOD OF FORMING THE SAME

(75) Inventor: Robert Sichenzia, Long Island, NY (US)

Correspondence Address: HOGAN LOVELLS US LLP, ONE TABOR CENTER, SUITE 1500, 1200 SEVENTEENTH ST, DENVER, CO, 80202, US

(73) Assignee: Aeroflex Microelectronic Solutions, Long Island, NY (US)

(21) Appl. No.: 12/842,906

(22) Filed: Jul. 23, 2010

Related U.S. Application Data
(60) Provisional application No. 61/228,490, filed on Jul. 24, 2009.

(51) Int. Cl. H01L 23/48; H01L 21/54

(52) U.S. Cl. 257/692; 438/121; 257/E23.011; 257/E21.501

(57) ABSTRACT

The invention relates to a hermetically sealed semiconductor module and more particularly to repacking a non-hermetically sealed semiconductor module thereby forming a hermetically sealed semiconductor module.

This application claims the benefit of U.S. Provisional Patent Application No. 61/228,490, filed on Jul. 24, 2009, which is hereby incorporated by reference for all purposes as if fully set forth herein.

### BACKGROUND OF THE INVENTION

### Field of the Invention

The invention relates to a hermetically sealed semiconductor module and more particularly to repacking a non-hermetically sealed semiconductor module thereby forming a hermetically sealed semiconductor module.

### SUMMARY OF THE INVENTION

Accordingly, the invention is directed to hermetic packaging and methods of forming the same that substantially obviate one or more of the problems due to limitations and disadvantages of the related art.

An advantage of the invention is to provide a cost effective method of hermetically sealing a non-hermetically sealed semiconductor module.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the invention, an embodiment of the invention is directed towards a hermetically sealed apparatus. The apparatus includes a first lead arranged on a substrate. The substrate has a plurality of hermetically sealed conductive interconnects arranged through at least a portion of the substrate and electrically coupled to the first lead. A semiconductor module including a second lead is electrically coupled to the first lead with the interconnects. A ring frame is arranged on the periphery of the semiconductor module; the ring frame is hermetically sealed to the substrate. A lid is hermetically sealed to the ring frame such that the lid, the ring frame, and the substrate hermetically seal the semiconductor module.

Another embodiment of the invention is directed towards a hermetically sealed semiconductor module. A plurality of first leads is arranged on a ceramic substrate. The ceramic substrate has a plurality of hermetically sealed conductive interconnects through the ceramic substrate that are capable of providing an electrical connection to the plurality of first leads. A semiconductor module includes a plurality of second leads electrically coupled to the plurality of first leads with the interconnects. A ring frame is arranged on the periphery of the semiconductor module and the ring frame is hermetically sealed to the substrate. A lid is hermetically sealed to the ring frame such that the ring frame, substrate, and lid hermetically seal the semiconductor module.

Yet another embodiment of the invention is directed towards a method of forming a hermetically sealed semiconductor module. The method includes providing a non-hermetically sealed semiconductor module, providing a substrate and forming a plurality of hermetically sealed interconnects through the substrate. A plurality of first leads is formed on the substrate and the semiconductor module is arranged on the substrate. The semiconductor module has a plurality of second leads electrically coupled to the plurality of first leads with the interconnects. A ring frame is formed around a periphery of the semiconductor module and the ring frame is hermetically sealed to the substrate. A lid is hermetically sealed to the ring frame.

Still another embodiment of the invention is directed to a repacking kit for hermetically sealing a non-hermetically sealed semiconductor component. The repacking kit includes a ceramic substrate having a plurality of conductive portions capable of being electrically coupled to a non-hermetically sealed semiconductor component. A ring frame and lid are also provided and both are capable of forming a hermetic seal around the non-hermetically sealed semiconductor component.

It is to be understood that both the foregoing general description and the following detailed description are exemplary and explanatory and are intended to provide further explanation of the invention as claimed.

### BRIEF DESCRIPTION OF THE DRAWINGS

The accompanying drawings are included to provide a further understanding of the invention and are incorporated in and constitute a part of this specification, illustrate embodiments of the invention and, together with the description, serve to explain the principles of the invention.

In the drawings:

FIG. 1A is a perspective view of a hermetically sealed semiconductor module;

FIG. 1B is an exploded view of the hermetically sealed semiconductor module of FIG. 1A;

FIG. 1C is a top down view of the hermetically sealed semiconductor module of FIG. 1A;

FIG. 1D is a side view of the hermetically sealed semiconductor module of FIG. 1A;

FIG. 1E is an end view of the hermetically sealed semiconductor module of FIG. 1A; and

FIG. 1F is a cross section view of the hermetically sealed semiconductor module taken along line A to A′ of FIG. 1A.

### DETAILED DESCRIPTION OF THE ILLUSTRATED EMBODIMENTS

Embodiments of the invention are directed towards hermetic packaging and more particularly to repacking a non-hermetically sealed semiconductor module, thereby forming a hermetically sealed semiconductor module.

In one embodiment, a hermetically sealed apparatus includes a first lead arranged on a substrate. The substrate may include a ceramic material such as alumina, aluminum nitrite, beryllium oxide and combinations thereof. The substrate can have a thickness ranging from about 20 mm to about 100 mm. More preferably, the substrate has a thickness in the range from about 40 mm to about 60 mm. The substrate has a plurality of hermetically sealed conductive interconnects arranged through at least a portion of the substrate. The conductive material may include any conductive material such as copper, and alloys of the same. A first lead is arranged on the substrate and electrically coupled to the conductive portions of the substrate. A semiconductor module, e.g., non-hermetically sealed module, has a second lead electrically coupled to the first lead with the conductive portions.

A ring frame is arranged on the periphery of the semiconductor module, wherein the ring frame is hermetically sealed to the substrate, e.g., soldered or by other known sealing techniques. A lid is hermetically sealed to the ring frame such that the lid, the ring frame, and the substrate hermetically seal the semiconductor module. The lid is welded to the ring frame, e.g., resistance welded. The ring frame and lid are formed from an alloy material such as iron-nickel-cobalt alloy, e.g., KOVAR material.

The hermetic seal has characteristics including leak rates comparable to glass, good temperature performance, and low outgassing. In a preferred embodiment, the leak rate of the hermetically sealed semiconductor module is less than about 5.0×10⁻⁸ cc/sec. More specifically, the ring frame, substrate and lid form a hermetically sealed cavity for accepting and enclosing a semiconductor module. Of course, in other embodiments the cavity does not need to be hermetically sealed.

The semiconductor module may include any type of semiconductor module with or without preexisting leads. For example, the semiconductor module may be a dc-dc converter, power field effect transistor (FET) and the like. In a preferred embodiment, the semiconductor module is a power module as described in U.S. Pat. No. 6,940,013, which is hereby incorporated by reference. The semiconductor module preferably is a non-hermetically sealed module.

The first and second leads are formed from a conductive material such as copper, and alloys of the same. The first and second leads may include a plurality of leads where each lead includes a pair of legs, lying opposite each other, and each leg includes a first end and a second end. Other configurations as known in the art are also possible, e.g., J lead, double sided J lead, and the like. In a preferred embodiment, the first and second leads are bilateral J-lead connectors as described in U.S. Pat. No. 6,940,013, which is hereby incorporated reference as if fully set forth herein. The first lead also may have different geometry as compared to the second lead.

Another embodiment of the invention is directed towards a method of forming a hermetically sealed semiconductor module. The method includes providing a semiconductor module, e.g., non-hermetically sealed module, providing a substrate, e.g., ceramic substrate, and forming a plurality of hermetically sealed interconnects through the substrate. The plurality of hermetically sealed interconnects is formed by forming holes through the substrate by means known in the art, e.g., laser drilling. Conductive material is formed in the holes, thereby forming interconnects. In a preferred embodiment, the conductive material is hermetically formed in the substrate such that the interconnects are hermetically sealed in the substrate.

A plurality of first leads is attached to conductive interconnects on the substrate. A semiconductor module is attached or arranged on the substrate. The semiconductor module also has a plurality of second leads electrically coupled to the plurality of first leads via the interconnects. A ring frame is formed around a periphery of the semiconductor module and attached to the substrate. The ring frame is hermetically sealed to the substrate. A lid is welded to the ring frame, e.g., resistance welded, thereby forming a hermetically sealed cavity enclosed in the semiconductor module.

Another embodiment of the invention is directed towards a repacking kit for hermetically sealing a non-hermetically sealed semiconductor component. The repacking kit includes a ceramic substrate having a plurality of conductive portions capable of being electrically coupled to a non-hermetically sealed semiconductor component. A ring frame and lid capable of forming a hermetic seal around the non-hermetically sealed semiconductor component are also provided in the kit. The kit allows a consumer to easily reconfigure a non-hermetically sealed semiconductor module to be hermetically sealed without significant changes to the non-hermetically sealed semiconductor module. The kit also includes a plurality of first leads arranged on the substrate and electrically coupled to the conductive portions.

Reference will now be made in detail to an embodiment of the invention, an example of which is illustrated in the accompanying drawings.

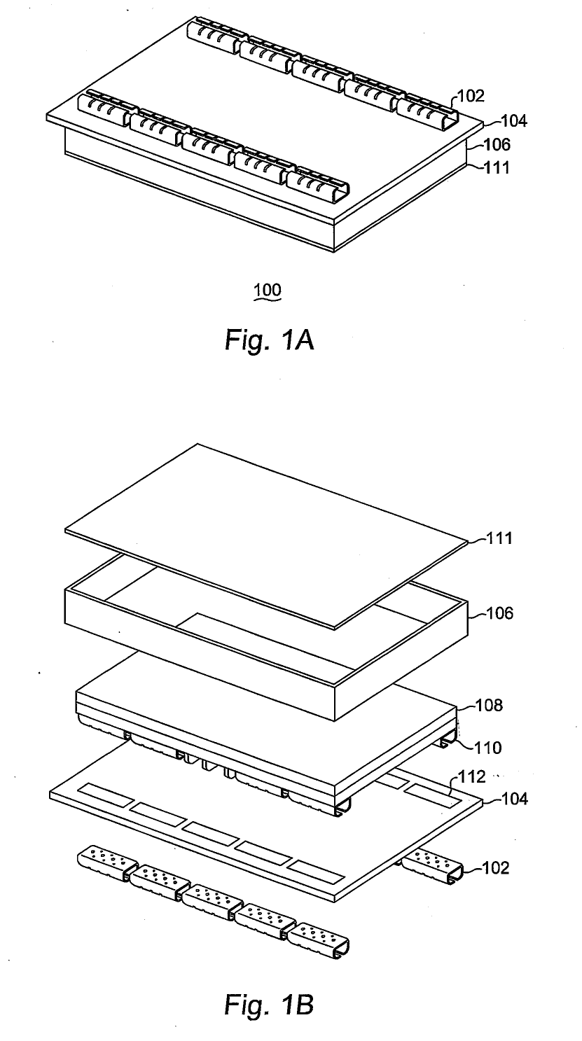

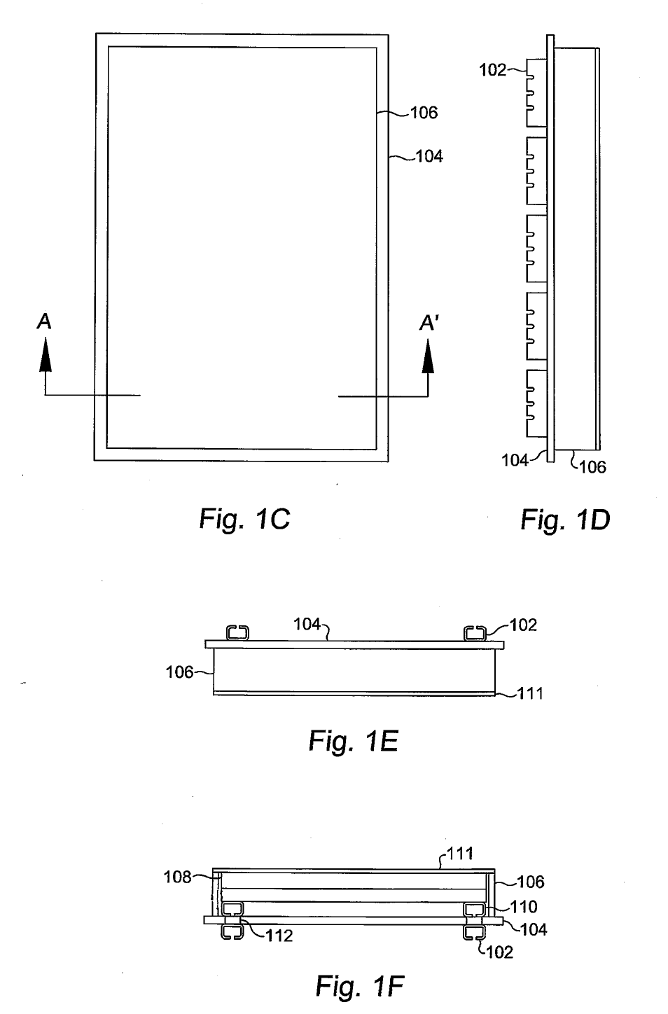

FIG. 1A is a perspective view of a hermetically sealed semiconductor module. FIG. 1B is an exploded view of the hermetically sealed semiconductor module. FIG. 1C is a top down view of the hermetically sealed semiconductor module. FIG. 1D is a side view of the hermetically sealed semiconductor module. FIG. 1E is an end view of the hermetically sealed semiconductor module. FIG. 1F is a cross section view of the hermetically sealed semiconductor module taken along line A to A′.

Referring to FIGS. 1A-1F, the hermetically sealed semiconductor module is depicted generally as reference number 100. The apparatus 100 includes a set of leads 102 attached to a bottom surface of the substrate 104. A ring frame 106 is arranged on the periphery of a semiconductor module 108. In a preferred embodiment, the semiconductor module includes is a non-hermetically sealed module. Optionally, there may be more than one semiconductor module. The lid 111 is arranged on the ring frame 106. In this embodiment, the ring frame 106 and lid 111 are an iron-nickel-cobalt alloy, e.g., KOVAR material. The ring frame 106 is soldered to the substrate 104 thereby forming a hermetic seal with the substrate. The lid 111 is welded, e.g., resistance welded to the ring frame 106, thereby forming a hermetic seal with the ring frame 106 and the lid 111.

The semiconductor module 108 is a power module as described in U.S. Pat. No. 6,940,013, which is hereby incorporated by reference. The semiconductor module 108 also includes a set of leads 110. The leads 102 and 110 are formed of a conductive material as also described in U.S. Pat. No. 6,940,013. In particular, the leads 110 include a plurality of leads; each lead includes a pair of legs and each leg includes a first end and a second end, the pair of legs lying opposite each other.

The substrate 104 is an alumina ceramic. Laser holes are cut through the substrate in a plurality of locations. The holes are then filed with a conductive material thereby forming interconnects 112 through the substrate. The conductive material can be formed hermetically as known to one of ordinary skill in the art. The interconnects 112 allow for electrical contact through the substrate. In a preferred embodiment, the conductive material is copper.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A hermetically sealed apparatus, comprising:
a first lead arranged on a substrate, wherein the substrate has a plurality of hermetically sealed conductive interconnects arranged through at least a portion of the substrate and electrically coupled to the first lead;
a semiconductor module comprising a second lead electrically coupled to the first lead with the interconnects;
a ring frame arranged on the periphery of the semiconductor module, wherein the ring frame is hermetically sealed to the substrate; and
a lid hermetically sealed to the ring frame, wherein the lid, the ring frame, and the substrate hermetically seal the semiconductor module.

2. The apparatus of claim 1, wherein the semiconductor module comprises a non-hermetically sealed power converter.

3. The apparatus of claim 1, wherein the semiconductor module comprises a non-hermetically sealed power field effect transistor.

4. The apparatus of claim 1, wherein the second lead comprises a plurality of leads.

5. The apparatus of claim 4, wherein at least one of the plurality of leads comprises a pair of legs, each leg comprising a first end and a second end, the pair of legs lying opposite each other.

6. The apparatus of claim 1, wherein the second lead comprises copper.

7. The apparatus of claim 1, wherein the substrate comprises a ceramic material selected from the group consisting of alumina, aluminum nitrite, beryllium oxide and combinations thereof.

8. The apparatus of claim 1, wherein the first lead comprises a plurality of leads.

9. The apparatus of claim 8, wherein at least one of the plurality of leads comprises a pair of legs, each leg comprising a first end and a second end, the pair of legs lying opposite each other.

10. The apparatus of claim 1, wherein the ring frame and the lid comprises an alloy material.

11. The apparatus of claim 10, wherein the alloy material comprises nickel cobalt ferrous alloy.

12. The apparatus of claim 1, wherein the hermetically sealed semiconductor module has a gas leak rate of less than about 5.0×10⁻⁸ cc/sec.

13. A hermetically sealed semiconductor module, comprising:
a plurality of first leads arranged on a ceramic substrate, wherein the ceramic substrate has a plurality of hermetically sealed conductive interconnects through the ceramic substrate capable of providing an electrical connection to the plurality of first leads;
a semiconductor module comprising a plurality of second leads electrically coupled to the plurality of first leads with the interconnects;
a ring frame arranged on the periphery of the semiconductor module, wherein the ring frame is hermetically sealed to the substrate; and
a lid hermetically sealed to the ring frame, wherein the ring frame, substrate and lid hermetically seal the semiconductor module.

14. The module of claim 13, wherein the hermetically sealed semiconductor module has a gas leak rate of less than about 5.0×10⁻⁸ cc/sec.

15. A method of forming a hermetically sealed semiconductor module, comprising the steps of:
providing a non-hermetically sealed semiconductor module;
providing a substrate;
forming a plurality of hermetically sealed interconnects through the substrate;
forming a plurality of first leads on the substrate;
arranging the semiconductor module on the substrate, wherein the semiconductor module has a plurality of second leads electrically coupled to the plurality of first leads with the interconnects;
forming a ring frame around a periphery of the semiconductor module, wherein the ring frame is hermetically sealed to the substrate; and
hermetically sealing a lid to the ring frame.

16. The method of claim 15, wherein the semiconductor module comprises a dc-dc converter.

17. The method of claim 15, wherein the forming a plurality of hermetically sealed interconnects step, comprises the steps of:
forming a plurality of holes through the substrate; and
forming a plurality of conductive material in the plurality of holes in the substrate.

18. The method of claim 17, wherein the forming a plurality of holes step comprises laser drilling a plurality of holes through the substrate.

19. The method of claim 15, wherein the substrate comprises a ceramic material selected from the group consisting of alumina, aluminum nitrite, beryllium oxide and combinations thereof.

20. The method of claim 15, wherein the hermetically sealed semiconductor module has a gas leak rate of less than about of less than about 5.0×10-8 cc/sec.

21. The method of claim 15, wherein the substrate comprises a ceramic material selected from the group consisting of alumina, aluminum nitrite, beryllium oxide and combinations thereof.

22. The method of claim 15, wherein at least one of the plurality of leads comprises a pair of legs, each leg comprising a first end and a second end, the pair of legs lying opposite each other.

23. A repacking kit for hermetically sealing a non-hermetically sealed semiconductor component, comprising:
a ceramic substrate having a plurality of conductive portions capable of being electrically coupled to a non-hermetically sealed semiconductor component; and
a ring frame and lid capable of forming a hermetic seal around the non-hermetically sealed semiconductor component.

24. The repacking kit of claim 23 further comprising a plurality of first leads arranged on the substrate and electrically coupled to the conductive portions.

25. The repacking kit of claim 23, wherein the repacking kit is capable of providing a hermetic seal, hermetically sealing the non-hermetically sealed semiconductor component with a gas leak rate of less than about 5.0×10⁻⁸ cc/sec.
